(19) United States
(12) Patent Application Publication
(10) Pub. No.: US 2015/0091664 A1
(43) Pub. Date: Apr. 2, 2015

(54) CIRCUIT DEVICE, OSCILLATOR, ELECTRONIC APPARATUS, AND MOVING OBJECT

(71) Applicant: Seiko Epson Corporation, Tokyo (JP)

(72) Inventor: Hisahiro ITO, Minowa (JP)

(21) Appl. No.: 14/497,854

(22) Filed: Sep. 26, 2014

(30) Foreign Application Priority Data
Sep. 30, 2013 (JP) 2013-203865

(51) Int. Cl. H03L 7/02; H03B 5/30

(52) U.S. Cl. CPC H03L 7/02; H03B 5/30
USPC 331/158

(57) ABSTRACT

A circuit device includes an oscillation circuit that includes a variable capacitance circuit and performs an operation of oscillating an oscillation element; and a control unit. The variable capacitance circuit includes a plurality of variable capacitance elements. When an operation mode is a first operation mode, the control unit supplies applied voltages in which at least one thereof is a variable voltage to the plurality of variable capacitance elements, and when the operation mode is a second operation mode, the control unit supplies applied voltages which are all fixed voltages to the plurality of variable capacitance elements.

### BACKGROUND

1. Technical Field

The present invention relates to a circuit device, an oscillator, an electronic apparatus, and a moving object.

2. Related Art

In the related art, a voltage controlled oscillator referred to as a Voltage controlled Crystal Oscillator (VCXO) in which an oscillating frequency is controlled to be variable by a control voltage and an oscillator referred to as a Simple Packaged Crystal Oscillator (SPXO) without a voltage control function of the oscillation frequency are known. As a technique of such an oscillator in the related art, for example, techniques disclosed in JP-A-2006-245982 and JP-A-2005-303388 are known.

A circuit device (IC) controlling oscillation of an oscillation element such as a crystal vibrator or the like is incorporated in an oscillator. Further, in the related art, a circuit device developed for a VCXO is incorporated in a VCXO and a circuit device developed for an SPXO is incorporated in an SPXO in general. Accordingly, there is a problem in that inventory management becomes complicated because one circuit device cannot comply with both of the VCXO and the SPXO.

From this viewpoint, JP-A-2005-303388 discloses a technique in the related art which can use the VCXO as the SPXO by cutting the fusing element provided in a transmission path of a control voltage.

However, the technique of JP-A-2005-303388 in the related art has a problem in terms of improvement of frequency stability or accuracy of an oscillation frequency.

### SUMMARY

An advantage of some aspects of the invention is to provide a circuit device, an oscillator, an electronic apparatus, and a moving object which can comply with both of a voltage controlled oscillator and an oscillator without a voltage control function and can achieve improvement of frequency stability of an oscillation frequency.

### Application Example 1

This application example relates to a circuit device including an oscillation circuit that includes a variable capacitance circuit and performs an operation of oscillating a vibrator; and a control unit, in which the variable capacitance circuit includes first to n-th variable capacitance elements (where, n is an integer of 2 or more), when an operation mode is a first operation mode, the control unit supplies first to n-th applied voltages in which at least one of the applied voltages is a variable voltage to the first to n-th variable capacitance elements, and when the operation mode is a second operation mode, the control unit supplies the first to n-th applied voltages which are fixed voltages to the first to n-th variable capacitance elements.

According to this application example, the variable capacitance circuit has the first to n-th variable capacitance elements. In addition, in the first operation mode, the control unit supplies the first to n-th applied voltages in which at least one thereof is a variable voltage to the first to n-th variable capacitance elements. In this manner, since the variable voltage is applied to at least one of the first to n-th variable capacitance elements, the circuit device can be operated as a circuit device for the voltage controlled oscillator. In contrast, in the second operation mode, the first to n-th applied voltages which are fixed voltages are supplied to the first to n-th variable capacitance elements. In this manner, since the fixed voltages are applied to the first to n-th variable capacitance elements, the circuit device can be operated as a circuit device for an oscillator without a voltage control function. Accordingly, it is possible to achieve improvement or the like of frequency stability of the oscillating frequency while complying with both the voltage controlled oscillator and the oscillator without the voltage control function.

### Application Example 2

According to this application example, the circuit device may further include an operation mode setting unit that sets the operation mode, the operation mode setting unit may include a storage unit that stores setting information of the operation mode, and the control unit may switch the first operation mode and the second operation mode based on the setting information.

With this configuration, the circuit device can be operated as a circuit device for the voltage controlled oscillator or as a circuit device for the oscillator without the voltage control function by switching the first operation mode and the second operation mode using setting information set in the storage unit.

### Application Example 3

According to this application example, the control unit may switch the first operation mode and the second operation mode using a control signal to be input.

With this configuration, the circuit device can be operated as a circuit device for the voltage controlled oscillator or as a circuit device for the oscillator without the voltage control function by switching the first operation mode and the second operation mode using the control signal to be input.

### Application Example 4

According to this application example, the control unit may include first to n-th switching units to which the variable voltage and the fixed voltage are input, and which outputs a voltage selected from the variable voltage and the fixed voltage to the first to n-th variable capacitance elements as the first to n-th applied voltages, when the operation mode is the first operation mode, at least one switching unit among the first to n-th switching units may select and output the variable voltage, and when the operation mode is the second operation mode, the first to n-th switching units may select and output the fixed voltage.

With this configuration, in the first operation mode, at least one switching unit among the first to n-th switching units can supply the first to n-th applied voltages in which at least one thereof is variable voltage to the first to n-th variable capacitance elements by selecting and outputting the variable voltage. Further, in the second operation mode, the first to n-th switching units can supply the first to n-th applied voltages which are fixed voltages to the first to n-th variable capacitance elements by selecting and outputting the fixed voltages.

### Application Example 5

According to this application example, the control unit may set frequency variable sensitivity of an oscillating frequency with respect to a control voltage which is the variable voltage by setting the number of times of supplying voltages which become variable voltages among the first to n-th applied voltages.

With this configuration, in the first operation mode, the frequency variable sensitivity of the oscillating frequency can be set while the circuit device is operated as a circuit device for the voltage controlled oscillator.

### Application Example 6

According to this application example, the circuit device may include a voltage generation circuit that generates the fixed voltage based on a reference voltage.

With this configuration, since the fixed voltages which can minimize fluctuation due to fluctuation of a power supply voltage can be used as the applied voltage of the variable capacitance element, the frequency stability or the like of the oscillating frequency can be improved.

### Application Example 7

According to this application example, the first operation mode may be a mode in which the oscillating frequency is changed according to a change of the control voltage which is the variable voltage, and when the control voltage is set as a nominal frequency voltage while the oscillating frequency is set as a nominal frequency in the first operation mode, the voltage generation circuit may generate the nominal frequency voltage as the fixed voltage.

With this configuration, in a case where the nominal frequency in the first operation mode is the oscillating frequency when the control voltage is set to the nominal frequency voltage, the fixed voltage is set to the nominal frequency voltage and then applied to the first to n-th variable capacitance elements in the second operation mode. Accordingly, when the oscillating frequency is adjusted so as to be the nominal frequency in the first operation mode, the oscillating frequency in the second operation mode is also adjusted to the nominal frequency. Therefore, adjustment of the oscillating frequency can be made in an efficient and simple manner.

### Application Example 8

According to this application example, the circuit device may further include a control voltage input terminal to which the control voltage which is the variable voltage is input, the first operation mode may be a mode in which the oscillating frequency is changed according to a change of the control voltage, and the second operation mode may be a mode in which the oscillating frequency is constant with respect to the change of the control voltage.

With this configuration, the oscillating frequency is controlled to be variable by the control voltage to be input to the control voltage input terminal in the first operation mode and the oscillating frequency can be controlled to be constant without depending on the control voltage in the second operation mode.

### Application Example 9

This application example relates to an oscillator including the circuit device and the oscillation element described above.

### Application Example 10

This application example relates to an electronic apparatus including the circuit device described above.

### Application Example 11

This application example relates to a moving object including the circuit device described above.

### BRIEF DESCRIPTION OF THE DRAWINGS

The invention will be described with reference to the accompanying drawings, wherein like numbers reference like elements.

FIGS. 1A to 1C are explanatory diagrams describing problems of a VCXO.

FIG. 2 illustrates a configuration example of a circuit device and an oscillator including the circuit device of the present embodiment.

FIG. 3 illustrates a modification example of the present embodiment.

FIG. 4 illustrates a configuration example of an oscillation circuit.

FIG. 5 illustrates a configuration example of a control unit and a variable capacitance circuit.

FIG. 6 illustrates a configuration example of the control unit and the variable capacitance circuit.

FIGS. 7A and 7B are explanatory diagrams describing a method of setting frequency variable sensitivity.

FIG. 8 illustrates a configuration example of a voltage generation circuit.

FIG. 9 is an explanatory diagram describing a method of adjusting an oscillating frequency.

FIGS. 10A and 10B illustrate configuration examples of an electronic apparatus and a moving object using the circuit device of the present embodiment.

### DESCRIPTION OF EXEMPLARY EMBODIMENTS

Hereinafter, preferred embodiments of the invention will be described in detail. Further, the present embodiments described below do not limit aspects of the invention and the whole configurations described in the present embodiments may not be necessary for solving the problem of the invention.

### 1. Circuit Device

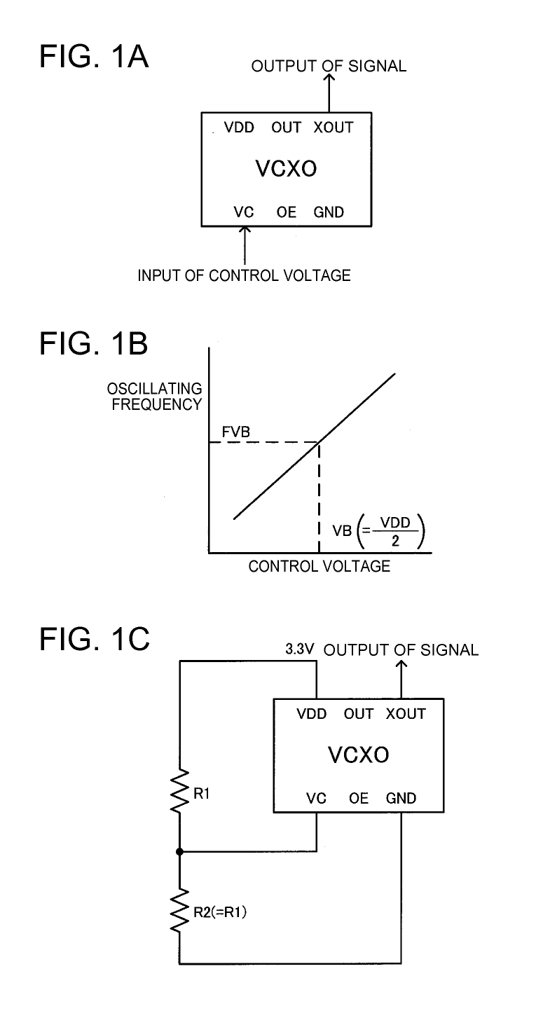

FIG. 1A illustrates a voltage controlled oscillator referred to as a VCXO. An input terminal of a control voltage is provided in the VCXO, and, as illustrated in FIG. 1B, an oscillating frequency can be controlled to be variable by a control voltage VC to be input to the input terminal.

In this case, in the VCXO, an oscillating frequency FVB at the time when the control voltage VC is VB is adjusted to be within nominal accuracy. Hereinafter, the oscillating frequency FVB is described as a nominal frequency and the voltage VB at the time of becoming a nominal frequency FVB is described as a nominal frequency voltage. The nominal frequency FVB is also referred to as a center frequency (center frequency in the range of the nominal frequency) of the VCXO in some cases, and the nominal frequency voltage VB is also referred to as a center voltage in some cases.

When a power supply voltage is VDD, the nominal frequency voltage (center voltage) VB is set to “VB=VDD/2” in general. That is, in the VCXO, the control voltage VC is adjusted such that the nominal frequency FVB (center frequency) at the time when the VB is VDD/2 is to be within the nominal accuracy, and such nominal frequency or nominal accuracy is described in the specification of an oscillator.

Further, in the circuit device (IC) for an oscillator as a product, when it is necessary to comply with a Voltage controlled Crystal Oscillator (VCXO) having a voltage control function and a Simple Packaged Crystal Oscillator (SPXO) without a function of allowing a frequency to be variable by a voltage, a method illustrated in FIG. 1C can be considered as a method of a comparative example in which the VCXO can be used as the SPXO. In the method, a voltage of VDD/2 is generated and input to an input terminal of the control voltage VC by resistor division of the power supply voltage VDD using resistors R1 and R2. For example, in a case where the VDD is 3.3 V, the control voltage when the VC is 1.65 V is input to the input terminal.

However, in this method, when the power supply voltage VDD fluctuates due to influence or the like of surrounding equipment, “the control voltage VC=VDD/2” also fluctuates. As a result, the oscillating frequency controlled by the control voltage VC also fluctuates, and this leads to a problem of reduction in frequency stability of the oscillating frequency with respect to the fluctuation of the power supply voltage.

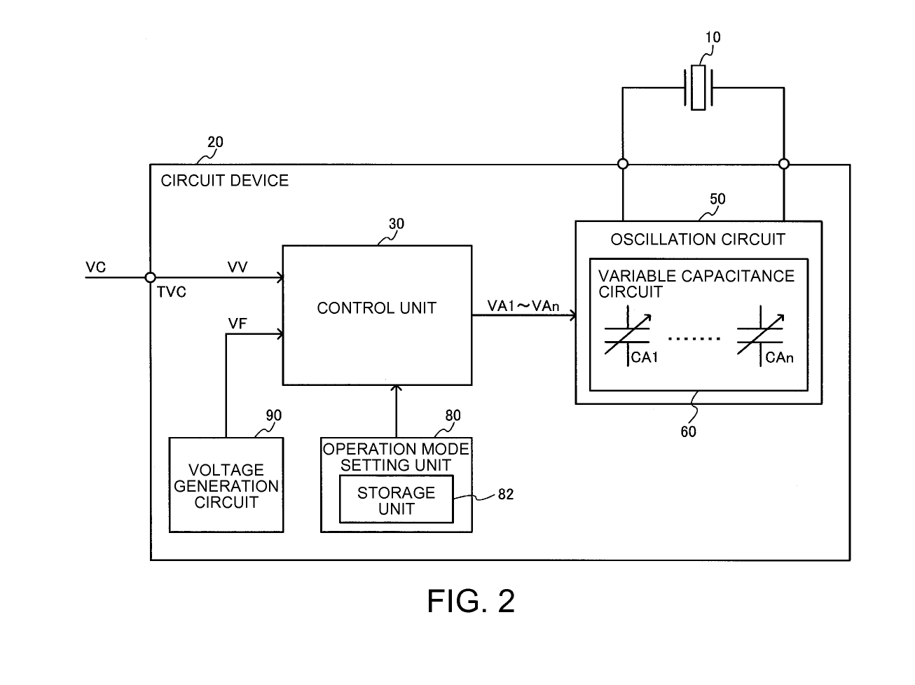

FIG. 2 illustrates configuration examples of a circuit device 20 and an oscillator including the circuit device 20 of the present embodiment, which solve the above-described problem. Further, the circuit device 20 and the oscillator of the present embodiment are not limited to the configuration of FIG. 2, and various modifications such that a part of the constituent components may be omitted or other constituent components are added are possible.

As illustrated in FIG. 2, the circuit device 20 of the present embodiment includes a control unit 30 and an oscillation circuit 50. Further, an operation mode setting unit 80 or a voltage generation circuit 90 can be included. In addition, the oscillator is configured of the circuit device 20 and an oscillation element 10. For example, the circuit device 20 and the oscillation element 10 are implemented by being incorporated in one package.

The oscillation element 10 is, for example, a crystal vibrator. In addition, as the oscillation element 10, a Surface Acoustic Wave (SAW) resonator, a Micro Electro Mechanical System (MEMS) resonator, or a crystal tuning fork type vibrator may be used.

The oscillation circuit 50 is a circuit performing an operation of oscillating the oscillation element 10 and includes a voltage control type variable capacitance circuit 60. A variable capacitance circuit 60 includes first to n-th variable capacitance elements CA1 to CAn (where, n is an integer of 2 or more). The variable capacitance elements CA1 to CAn are elements capable of controlling a capacitance value, and realized by, for example, a varicap (variable capacitance diode) or the like. The variable capacitance elements CA1 to CAn are connected, for example, in parallel. Further, the number n of the variable capacitance elements is arbitrary.

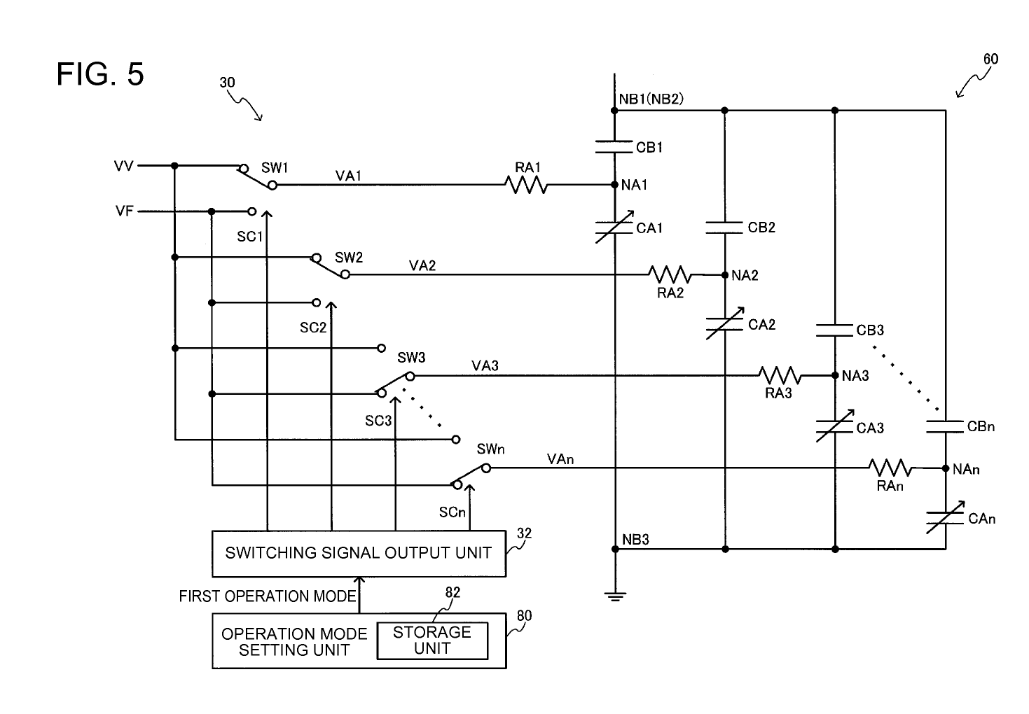

The control unit 30 controls the variable capacitance circuit 60 of the oscillation circuit 50, and supplies, for example, first to n-th applied voltages VA1 to VAn to the variable capacitance elements CA1 to CAn of the variable capacitance circuit 60. For example, the applied voltage VA1 is supplied to one terminal of the variable capacitance element CA1. Similarly, the applied voltage VA2 is supplied to one terminal of the variable capacitance element CA2 and the applied voltage VA3 is supplied to one terminal of the variable capacitance element CA3. The applied voltages VA4 to VAn are supplied to one terminal of the variable capacitance elements similarly which have the same n-th numbers. Further, a voltage of another terminal of the variable capacitance elements CA1 to CAn is set to, for example, aground voltage (GND). In addition, the set voltage of another terminal of the variable capacitance elements CA1 to CAn is not limited to the ground voltage. Moreover, other circuit elements (for example, resistors RA1 to RAn of FIG. 5 described below) may be interposed between an output node of the applied voltages VA1 to VAn of the control unit 30 and one terminal of the variable capacitance elements CA1 to CAn.

A variable voltage VV and a fixed voltage VF are input to the control unit 30. Specifically, the circuit device 20 includes a control voltage input terminal TVC to which the control voltage VC is input. Further, the control voltage VC to be input to the control voltage input terminal TVC is input to the control unit 30 as the variable voltage VV.

Further, the circuit device 20 includes a voltage generation circuit 90 and the voltage generation circuit 90 generates a fixed voltage VF. In addition, the fixed voltage VF generated by the voltage generation circuit 90 is input to the control unit 30. The voltage generation circuit 90 is, for example, a circuit generating the fixed voltage VF based on a reference voltage, and can be configured of a band-gap reference circuit or the like as described below. The voltage generation circuit 90 generates the fixed voltage VF whose fluctuation is minimized even in a case where the power supply voltage fluctuates or the temperature fluctuates, and supplies the fixed voltage VF to the control unit 30. Further, an embodiment in which the fixed voltage VF is supplied from the outside of the circuit device 20 is possible.

Further, the control unit 30 in the present embodiment supplies the applied voltages VA1 to VAn in which at least one thereof is the variable voltage VV to the variable capacitance elements CA1 to CAn in a case where the operation mode of the circuit device (the oscillation circuit, the oscillator) is the first operation mode. Specifically, the applied voltages VA1 to VAn in which at least one of the applied voltages thereof is the variable voltage VV and the rest of the applied voltages which are fixed voltages VF are supplied to one terminal of the variable capacitance element CA1 to CAn such that the numbers of A1 to An of the applied voltages are in one-to-one correspondence with those of the variable capacitance elements.

In contrast, the control unit 30 supplies the applied voltages VA1 to VAn which are fixed voltages VF to the variable capacitance elements CA1 to CAn when the operation mode is the second operation mode. That is, at least one of the applied voltages VA1 to VAn is the variable voltage VV in the first operation mode, but the applied voltages VA1 to VAn supplied to one terminal of the variable capacitance elements CA1 to CAn are all fixed voltages VF in the second operation mode.

Here, the first operation mode is a mode in which the oscillating frequency is changed according to a change of, for example, the control voltage VC which is the variable voltage VV. Specifically, the first operation mode is a mode in which the circuit device 20 is operated for, for example, the VCXO.

In contrast, the second operation mode is a mode in which the oscillating frequency is constant with respect to the change of the control voltage VC. That is, the second operation mode is a mode in which the oscillating frequency does not need to be variably controlled by the control voltage VC and, specifically, is a mode in which the circuit device 20 is operated for, for example, the SPXO.

In other words, the operation mode of the circuit device 20 is set to the first operation mode, the circuit device 20 can be operated for the VCXO, and the oscillator in which the circuit device 20 is incorporated can be operated as the VCXO. In contrast, when the operation mode of the circuit device 20 is set to the second operation mode, the circuit device 20 is operated for the SPXO and the oscillator in which the circuit device 20 is incorporated can be operated as for the SPXO.

The setting of the operation modes is performed by the operation mode setting unit 80. That is, the control unit 30 switches the above-described first operation mode and the second operation mode through instructions of the operation mode setting unit 80.

Specifically, the operation mode setting unit 80 includes a storage unit 82, and the storage unit 82 stores the setting information of the operation mode. In addition, the control unit 30 switches the first operation mode and the second operation mode based on the setting information stored in the storage unit 82. That is, the control unit 30 sets the operation mode to the first operation mode or to the second operation mode based on the setting information.

The storage unit 82 can be realized by a non-volatile memory such as an Electrically Erasable Programmable Read-Only Memory (EEPROM) or a One Time Programmable ROM (OTP). However, the storage unit 82, which is not limited thereto, may be a RAM (SRAM, DRAM) or a resistor configured of a flip-flop circuit or the like.

In addition, the control unit 30 in the present embodiment sets the frequency variable sensitivity of the oscillation frequency with respect to the control voltage VC by setting the number of times of supplying the voltages which become the variable voltages VV among the applied voltages VA1 to VAn. Here, the frequency variable sensitivity is a changing amount in a case where the oscillating frequency is changed with respect to a change of the control voltage VC. The frequency variable sensitivity corresponds to inclination of a characteristic curve of the oscillating frequency with respect to the control voltage VC of FIG. 1B.

According to the circuit device 20 of the present embodiment described above, in the first operation mode, at least one of the applied voltages VA1 to VAn to be supplied to the variable capacitance elements CA1 to CAn becomes the variable voltage VV. In this manner, since the variable voltage VV is applied to at least one of the variable capacitance elements CA1 to CAn, the circuit device 20 can be operated for, for example, the VCXO. That is, the circuit device 20 can be operated as the circuit device 20 for the voltage controlled oscillator.

In contrast, in the second operation mode, the applied voltages VA1 to VAn to be supplied to the variable capacitance elements CA1 to CAn become the fixed voltages VF. In this manner, since the fixed voltages VF are applied to the variable capacitance elements CA1 to CAn, the circuit device 20 can be operated for, for example, the SPXO. That is, the circuit device 20 can be operated as the circuit device 20 for the oscillator without the voltage control function.

Therefore, according to the present embodiment, since the circuit device 20 can be used for the VCXO and also can be used for the SPXO, the circuit device 20 can comply with both of the VCXO and the SPXO. For example, the circuit device 20 may be incorporated in the oscillator of the VCXO by setting the operation mode to the first operation mode in a case where the circuit device is used for the VCXO and the circuit device 20 may be incorporated in the oscillator of the SPXO by setting the operation mode to the second operation mode in a case where the circuit device is used for the SPXO. Consequently, since a single product of the circuit device 20 can comply with the VCXO and the SPXO, it is possible to reduce complexity of the inventory management and to reduce development cost and man-hours.

In the present embodiment, switching the operation mode is performed based on the setting information to be stored in the storage unit 82 of the operation mode setting unit 80. Accordingly, the circuit device 20 can be operated in the first operation mode or in the second operation mode by only rewriting the contents of the setting information to be stored in the storage unit 82. Therefore, even in a case where the circuit device 20 (IC) is treated as an inventory after the circuit device is produced, it is possible to accommodate a client who desires the VCXO by setting the setting information of the storage unit 82 to the setting information for the first operation mode. Further, it is possible to accommodate a client who desires the SPXO by setting the setting information of the storage unit 82 to the setting information for the second operation mode. Particularly, in a case where the storage unit is configured of a non-volatile memory whose setting information can be rewritten electrically, there is an advantage in that the operation mode can be changed even after the circuit device 20 is incorporated in a package of an oscillator.

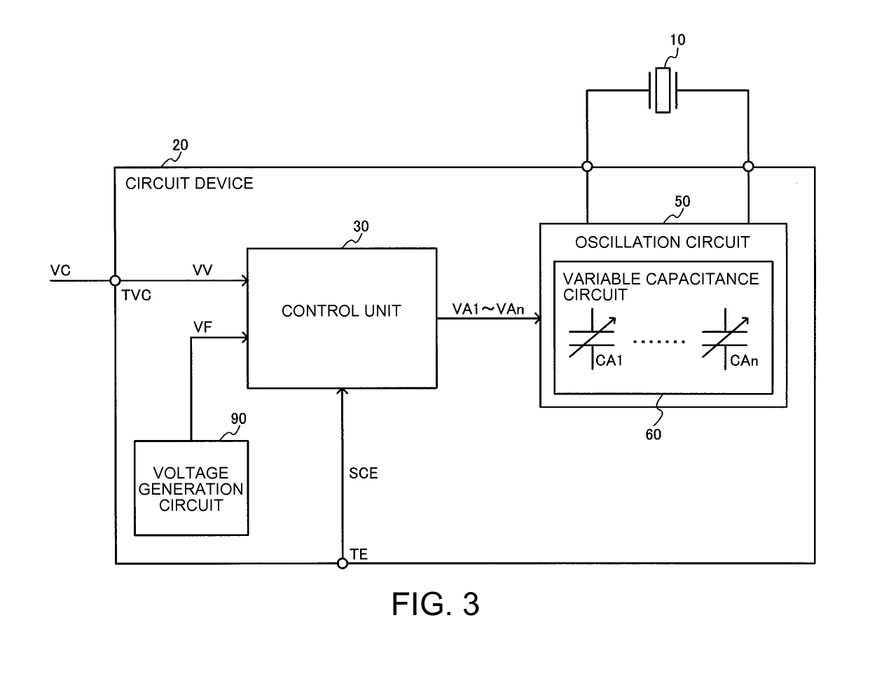

Moreover, FIG. 3 illustrates a modification example of the present embodiment. In this modification example, the control unit 30 switches the first operation mode and the second operation mode by a control signal SCE to be input. That is, since the control signal SCE is input to the control unit 30 directly from an external terminal TE, the operation mode can be switched based on the control signal SCE. Therefore, there is an advantage in that the operation mode can be freely switched by the control signal SCE to be input from an external device through the external terminal TE after the circuit device 20 is incorporated in the package of the oscillator. Further, in FIG. 3, a case where the number of the external terminals TE is one is exemplified, but the control signal SCE may be input by providing a plurality of the external terminals TE. For example, in a case where a p number of the external terminals TE are provided, p bits of the control signal SEC is input and then the operation mode may be set.

In addition, according to the circuit device 20 of the present embodiment, the frequency variable sensitivity of the oscillating frequency in the VCXO can be freely set by setting the number of times of supplying voltages which become the variable voltages VV among the applied voltages VA1 to VAn. Accordingly, it is possible to accommodate a client who desires frequency variable sensitivity of a first characteristic by setting the number of times of supplying voltages to become the variable voltages VV to the number corresponding to the frequency variable sensitivity of the first characteristic. Similarly, it is possible to accommodate a client who desires frequency variable sensitivity of a second characteristic by setting the number of times of supplying voltages to become the variable voltages VV to the number corresponding to the frequency variable sensitivity of the second characteristic.

Moreover, in the circuit device 20 of the present embodiment, the fixed voltage VF is generated by the voltage generation circuit 90 provided in the inside thereof. Accordingly, it is possible to minimize fluctuation of the fixed voltages VF with respect to the fluctuation of the temperature or the power supply voltage. In addition, since the fluctuation of the applied voltages to the variable capacitance elements CA1 to CAn can be minimized by minimizing the fluctuation of the fixed voltages VF, the frequency stability of the oscillating frequency with respect to the fluctuation of the temperature or the power supply voltage can be improved.

Further, in the technique in the related art disclosed in JP-A-2005-303388, the VCXO can be used as the SPXO by cutting the fusing element provided in the transmission path of the control voltage. Furthermore, the frequency variable sensitivity is adjusted using a buffer circuit configured of an operational amplifier.

However, in the technique in the related art, the frequency stability or accuracy of the oscillating frequency is degraded because of noise (thermal noise, 1/f noise) generated by the operational amplifier which is included in the buffer circuit. For example, when the operation amplifier which is a source of the noise is present in the path to which the control voltage is transmitted at the time of operation of the VCXO, the noise is superimposed on the control voltage and the oscillating frequency starts to fluctuate due to the superimposed noise. The fluctuation of the oscillating frequency leads to, for example, increase in phase noise, so that the frequency stability becomes unstable.

Moreover, when the operational amplifier is used for configuring the buffer circuit, this hinders low power consumption of the circuit device because a current flowing into a current path of the operation amplifier is large. Particularly, it is necessary to increase a bias current flowing into the operational amplifier for reducing the noise of the above-described operational amplifier, but this leads to an increase in power consumption.

Further, in the technique in the related art, there is a problem in that the original state of the VCXO cannot be returned after the oscillator is used as the SPXO by cutting the fusing element provided in the transmission path of the control voltage.

In contrast, according to the present embodiment, the circuit device 20 can be operated for the VCXO only by setting the operation mode of the circuit device 20 to the first operation mode and setting at least one of the applied voltages VA1 to VAn becomes the variable voltage VV. At this time, the frequency variable sensitivity of the oscillating frequency in the VCXO can be freely adjusted by setting the number of times of supplying the voltage which becomes the variable voltage VV. In addition, the circuit device 20 can be operated for the SPXO only by setting the operation mode of the circuit device 20 to the second operation mode and setting the applied voltages VA1 to VAn to become the fixed voltages VF. Therefore, according to the present embodiment, it is possible to comply with both of the VCXO and the SPXO and to adjust the frequency variable sensitivity in the VCXO without using the operational amplifier similar to that in the related art. That is, there is an advantage in that the circuit device 20 can comply with both of the VCXO and the SPXO and the frequency stability or power consumption can be improved compared to those in the related art. Further, there is an advantage in that it is possible to freely switch the first operation mode to the second operation mode and the second operation mode to the first operation mode by changing the setting information of the storage unit 82.

### 2. Configuration Example of Oscillation Circuit, Control Unit, and Variable Capacitance Circuit

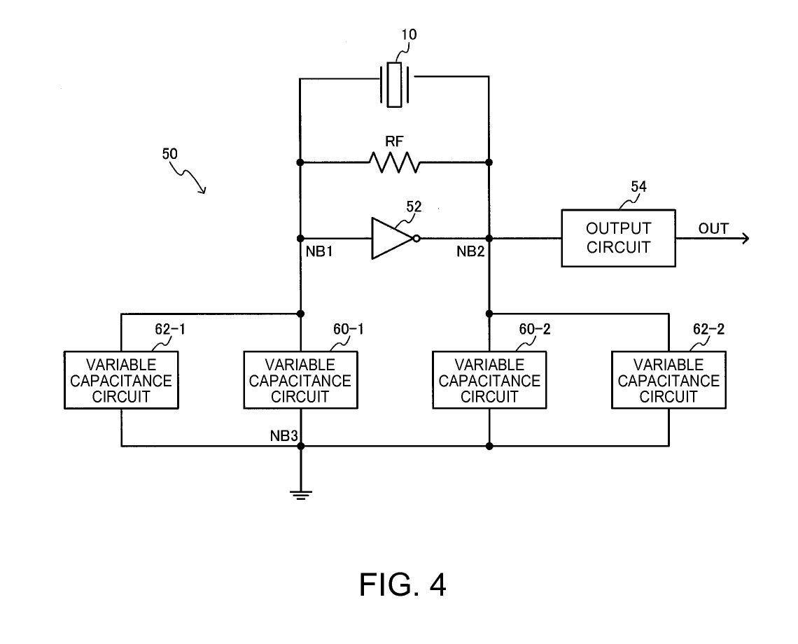

Next, configuration examples of the oscillation circuit 50 and the control unit 30 will be described in detail. FIG. 4 is a view illustrating a specific configuration example of the oscillation circuit 50.

The oscillation circuit 50 in FIG. 4 includes an inverter circuit 52, a feedback resistor RF, an output circuit 54, variable capacitance circuits 60-1 and 60-2, and variable capacitance circuits 62-1 and 62-2. The inverter circuit 52 functions as an amplifier of the oscillation signal. The feedback resistor RF is provided between an output node NB2 and an input node NB1 of the inverter circuit 52. An output signal of the inverter circuit 52 is buffered by the output circuit 54 to be output as a signal OUT.

The variable capacitance circuits 60-1 and 62-1 are connected to the input node NB1 of the inverter circuit 52 and the variable capacitance circuits 60-2 and 62-2 are connected to the output node NB2 of the inverter circuit 52.

The variable capacitance circuits 60-1 and 60-2 respectively correspond to the variable capacitance circuit 60 in FIG. 2 and include the variable capacitance elements CA1 to CAn which are connected in parallel in plural. The voltage control of the oscillating frequency in the VCXO is realized by controlling capacitance values of the variable capacitance circuits 60-1 and 60-2.

Meanwhile, the variable capacitance circuits 62-1 and 62-2 are capacitance circuits for minute adjustment of the oscillating frequency. Details of the variable capacitance circuits 62-1 and 62-2 will be described below.

FIG. 5 illustrates configuration examples of the control unit 30 and the variable capacitance circuit 60. Further, the configurations of the control unit 30 and the variable capacitance circuit 60 are not limited to the configurations of FIG. 5 and various modifications are possible. Since the variable capacitance circuits 60-1 and 60-2 of FIG. 4 have configurations which are the same as each other, the configuration thereof is described using the variable capacitance circuit 60 of FIG. 5.

As illustrated in FIG. 5, the control unit 30 includes the first to n-th switching units SW1 to SWn. These switching units SW1 to SWn can be realized by a switch or the like which is configured of a MOS transistor (transfer gate). However, the present embodiment is not limited thereto, and a modification in which the switching units SW1 to SWn can be realized by a circuit element other than the switch is possible.

The variable voltages VV and the fixed voltages VF are input to the switching units SW1 to SWn. In addition, the switching units SW1 to SWn output voltages selected from the variable voltages VV and the fixed voltages VF to the variable capacitance elements CA1 to CAn as the applied voltages VA1 to VAn. Specifically, the applied voltages VA1 to VAn are output to the variable capacitance elements CA1 to CAn through resistors RA1 to RAn for cutting an AC component.

The switching units SW1 to SWn perform switching control based on switching signals SC1 to SCn from a switching signal output unit 32 provided in the control unit 30. The switching signal output unit 32 outputs the switching signals SC1 to SCn based on the setting information from the operation mode setting unit 80.

The switching unit SW1 selects one of the variable voltage VV and the fixed voltage VF and outputs the selected voltage to one terminal of the variable capacitance element CA1 as the applied voltage VA1 based on the switching signal SC1. The switching unit SW2 selects one of the variable voltage VV and the fixed voltage VF and outputs the selected voltage to one terminal of the variable capacitance element CA2 as the applied voltage VA2 based on the switching signal SC2. The same applies to operations of other switching units SW3 to SWn.

A node NB3 of another terminal of the variable capacitance elements CA1 to CAn is set to a ground voltage (GND). Capacitance elements CB1 to CBn are provided between the node NB1 (NB2) and nodes NA1 to NAn of one terminal of the variable capacitance elements CA1 to CAn. The node NB1 (NB2) is an input node (output node) of the inverter circuit 52 as illustrated in FIG. 4.

That is, the capacitance element CB1 and the variable capacitance element CA1 are connected in series between the nodes NB1 and NB3. The capacitance element CB2 and the variable capacitance element CA2 are connected in series between the nodes NB1 and NB3. The same applies to connections of other capacitance elements CB3 to CBn and the variable capacitance elements CA3 to CAn.

The capacitance elements CB1 to CBn are elements whose capacitance values are fixed and can be realized by polysilicon capacitance or Metal-Insulator-Metal (MIM). The capacitance elements CB1 to CBn function as capacitance elements for cutting DC. The capacitance values of the capacitance elements CB1 to CBn are set to capacitance values larger (for example, approximately 10 times) than those of the variable capacitance elements CA1 to CAn. In this manner, in series capacitance values (for example, series capacitance values of the CA1 and the CB1), the capacitance values of the variable capacitance elements CA1 to CAn become dominant capacitance values. For example, it is assumed that the capacitance values of the variable capacitance elements CA1 and CB1 are CA and CB respectively. From this assumption, the series capacitance values of the CA1 and CB1 become “CS=1/{1/CA+1/CB}.” Accordingly, when the CB is sufficiently large, the series capacitance value CS becomes a value close to the capacitance value CA of the variable capacitance element.

Further, in FIG. 5, the operation mode setting unit 80 sets the operation mode to the first operation mode. In the first operation mode, at least one switching unit among the switching units SW1 to SWn selects and outputs the variable voltage VV. For example, in FIG. 5, the switching units SW1 and SW2 select the variable voltage VV and output the selected variable voltage VV to one terminal of the variable capacitance elements CA1 and CA2. In this manner, the switching units SW3 and SWn select the fixed voltage VF and output the selected fixed voltage VF to one terminal of the variable capacitance elements CA3 and CAn.

In this manner, in the first operation mode, some switching units among the switching units SW1 to SWn output the variable voltage VV and other switching units output the fixed voltage VF. Accordingly, as described above, the circuit device 20 can be operated for the VCXO. Further, all of the switching units SW1 to SWn may output the variable voltage VV.

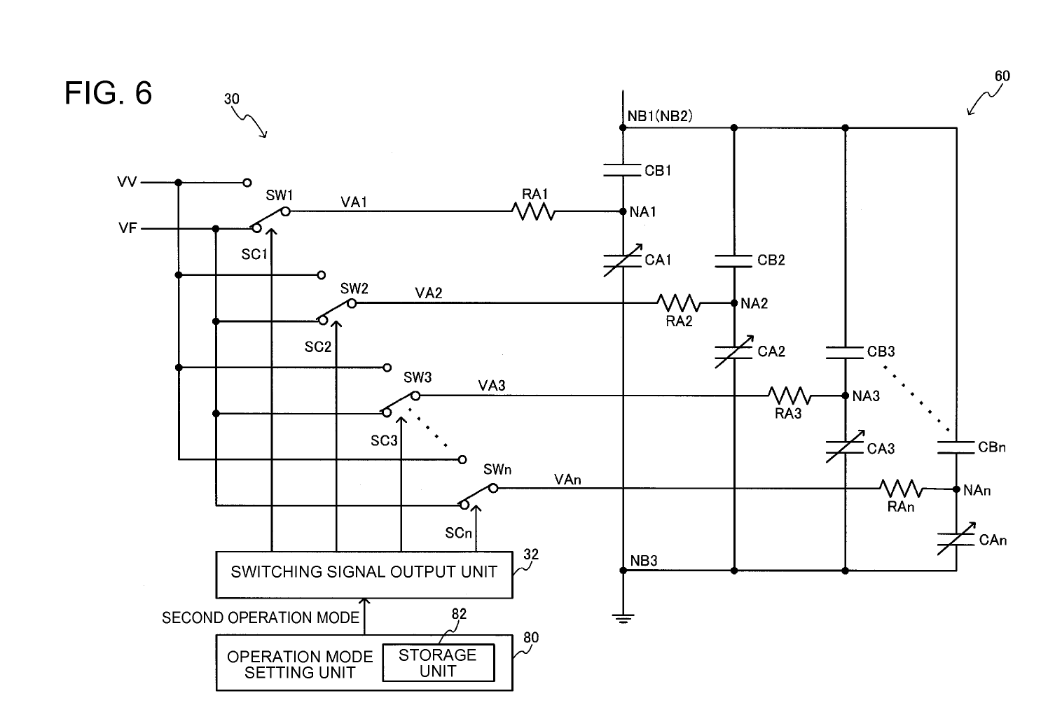

In contrast, in FIG. 6, the operation mode setting unit 80 sets the operation mode to the second operation mode. Further, in the second operation mode, the switching units SW1 to SWn select and output the fixed voltage VF.

In this manner, in the second operation mode, all of the switching units SW1 to SWn select the fixed voltage VF and output the selected fixed voltage VF to the variable capacitance elements CA1 to CAn. Accordingly, as described above, the circuit device 20 can be operated for the SPXO.

Specifically, the storage unit 82 of the operation mode setting unit 80 stores [b1, b2, b3, . . . , bn] as setting information. Respective b1, b2, b3, . . . , bn are set either to “0” (first logic level) or “1” (second logic level). Switching signals SC1, SC2, SC3, . . . , SCn output by the switching signal output unit 32 are controlled by the setting information [b1, b2, b3, . . . , bn].

For example, in a case where b1 is 1, the switching signal SC1 becomes, for example, an H level, and the switching unit SW1 selects the variable voltage VV. In this manner, the variable voltage VV is applied to the variable capacitance element CA1. Meanwhile, in a case where b1 is 0, the switching signal SC1 becomes, for example, an L level, and the switching unit SW1 selects the fixed voltage VF. In this manner, the fixed voltage VF is applied to the variable capacitance element CA1.

Similarly, in a case where b2 is 1, the switching signal SC2 becomes, for example, an H level, and the switching unit SW2 selects the variable voltage VV. In this manner, the variable voltage VV is applied to the variable capacitance element CA2. In contrast, in a case where b2 is 0, the switching signal SC2 becomes, for example, an L level, and the switching unit SW2 selects the fixed voltage VF. In this manner, the fixed voltage VF is applied to the variable capacitance element CA2.

In addition, in the first operation mode in FIG. 5, at least one of b1, b2, b3, . . . , bn of the setting information becomes “1.” In this manner, the variable voltage VV is applied to at least one of the variable capacitance elements CA1 to CAn.

Meanwhile, in the second operation mode in FIG. 6, all of b1, b2, b3, . . . , bn of the setting information become “0.” In this manner, the fixed voltage VF is applied to all of the variable capacitance elements CA1 to CAn.

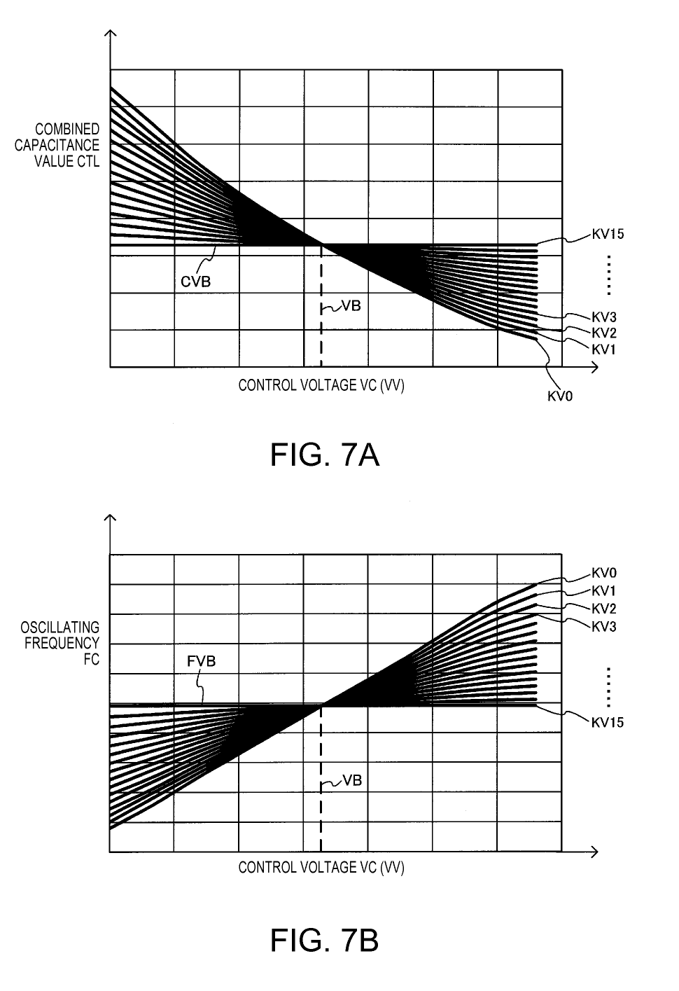

FIG. 7A is a view illustrating a relationship between the control voltage VC (variable voltage VV) and a combined capacitance value CT1 (combined capacitance value of load capacitance) and FIG. 7B is a view illustrating a relationship between the control voltage VC and an oscillating frequency FC.

Here, a case where the number n of the variable capacitance elements CA1 to CAn in FIGS. 5 and 6 is 15 will be described as an example.

The number m of KVm provided to each characteristic curve in FIGS. 7A and 7B represents the number of the variable capacitance elements to which the fixed voltage VF is applied, among the variable capacitance elements CA1 to CAn when the number n is 15.

For example, a KV1 is a characteristic curve in a case where the fixed voltage VF is applied to one variable capacitance element. That is, the KV1 is a characteristic curve in a case where the fixed voltage VF is applied to one variable capacitance element and the variable voltage VV is applied to fourteen variable capacitance elements.

Similarly, a KV2 is a characteristic curve in a case where the fixed voltage VF is applied to two variable capacitance elements and the variable voltage VV is applied to thirteen variable capacitance elements.

Further, a KV0 is a characteristic curve in a case where the fixed voltage VF is not applied to the variable capacitance elements and the variable voltage VV is applied to all of the variable capacitance elements.

Moreover, a KV15 is a characteristic curve in a case where the fixed voltage VF is applied to all fifteen variable capacitance elements.

For example, it is assumed that the number j of the variable capacitance elements to which the variable voltage VV is applied is set to j=15−m. From this assumption, as is obvious from FIG. 7B, the frequency variable sensitivity of the oscillating frequency FC can be set with respect to the control voltage VC by setting the number j of the variable capacitance elements.

For example, in the characteristic curve KV0, since m is 0, the number j of the variable capacitance elements to which the variable voltage VV is applied becomes “j=15−0=15.” That is, the variable voltage VV is applied to all variable capacitance elements, and the inclination of the characteristic curve KV0 becomes large in this case, so that the frequency variable sensitivity becomes large.

Moreover, in the characteristic curve KV1, since m is 1, the number j of the variable capacitance elements to which the variable voltage VV is applied becomes “j=15−1=14.” That is, the variable voltage VV is applied to fourteen variable capacitance elements and the fixed voltage VF is applied to one variable capacitance element. In this case, the inclination of the characteristic curve KV1 becomes smaller compared to the case of the characteristic curve KV0 and the frequency variable sensitivity becomes smaller compared to the case of the characteristic curve KV0.

Further, in the characteristic curve KV2, since m is 2, the number j of the variable capacitance elements to which the variable voltage VV is applied becomes “j=15−2=13.” That is, the variable voltage VV is applied to thirteen variable capacitance elements and the fixed voltage VF is applied to two variable capacitance elements. In this case, the inclination of the characteristic curve KV2 becomes smaller compared to the case of the characteristic curve KV1 and the frequency variable sensitivity becomes smaller compared to the case of the characteristic curve KV1.

Further, in the characteristic curve KV15, since m is 15, the number j of the variable capacitance elements to which the variable voltage VV is applied becomes “j=15−15=0.” That is, the fixed voltage VF is applied to all fifteen variable capacitance elements. In this case, the inclination of the characteristic curve KV15 becomes 0.

In this manner, the characteristic curve KV15 of FIG. 7B corresponds to the characteristic curve in the second operation mode for the SPXO. That is, in the second operation mode as illustrated in FIG. 6, the fixed voltage VF is applied to all variable capacitance elements CA1 to CA15. Accordingly, as in the case of the characteristic curve KV15 of FIG. 7B, a characteristic of the oscillating frequency in the SPXO, in which the oscillating frequency FC is not changed even when the control voltage VC is changed, can be obtained.

Meanwhile, the characteristic curves KV0 to KV14 of FIG. 7B correspond to characteristic curves in the first operation mode for the VCXO. That is, in the first operation mode as illustrated in FIG. 5, the variable voltage VV is applied to at least one of variable capacitance elements CA1 to CA15. In addition, by the setting of the number j of the variable capacitance elements, to which the variable voltage VV is applied, of “j=15−m,” the inclinations of the characteristic curves KV0 to KV14 are changed and the frequency variable sensitivity can be freely adjusted. This corresponds to the case where the frequency variable sensitivity is adjusted by setting the number of supplying of the voltage which becomes the variable voltage VV among the applied voltages VA1 to VAn described above.

In this manner, according to the circuit device of the present embodiment, it is possible to comply with both of the VCXO and the SPXO and to freely adjust the frequency variable sensitivity in the VCXO.

### 3. Voltage Generation Circuit

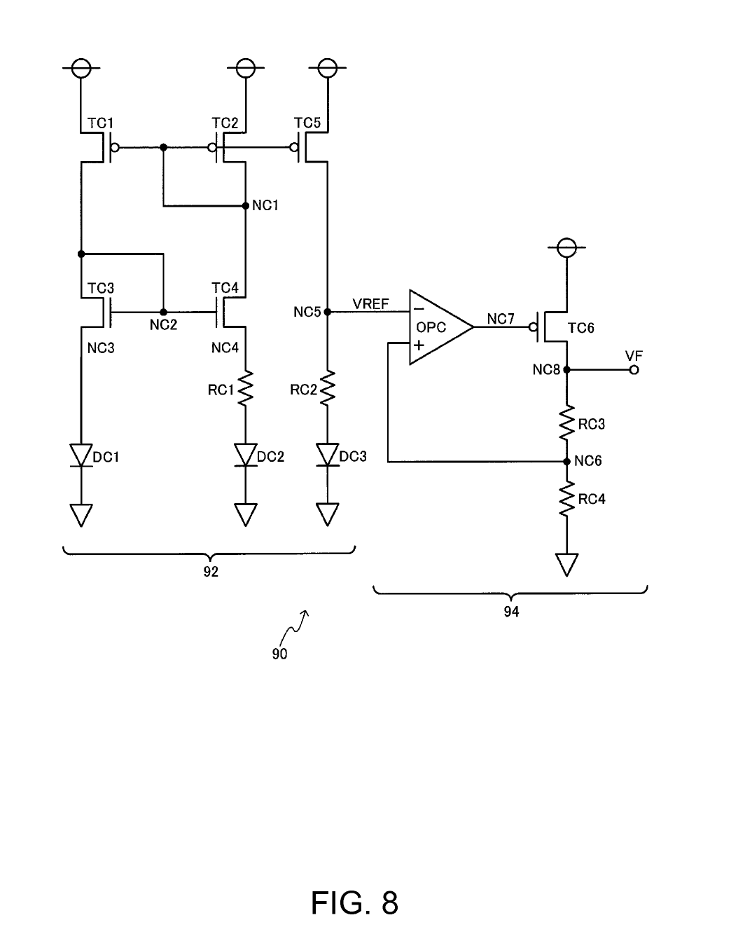

FIG. 8 illustrates a configuration example of the voltage generation circuit 90. The voltage generation circuit 90 includes a reference voltage generation circuit 92 (band-gap reference circuit) and a voltage regulator circuit 94.

The reference voltage generation circuit 92 is a circuit which generates a reference voltage VREF by band-gap reference, and includes transistors TC1 to TC5, resistors RC1 and RC2, and diodes DC1 to DC3. Further, currents having current values which are the same as each other flow in the diodes DC1 and DC2 by a current mirror circuit configured of the transistors TC1 and TC2, and TC3 and TC4. In addition, the reference voltage VREF is generated using the voltage which appears at both ends of the resistor RC1 by a source potential of the transistor TC3 being the same as a source potential of the transistor TC4. The reference voltage VREF can be generated without depending on the fluctuation of the temperature by appropriately selecting the resistance ratio of the resistor RC1 to the resistor RC2. The reference voltage VREF corresponds to the band-gap and energy of silicon, and, for example, VREF becomes 1.25 V.

The voltage regulator circuit 94 includes an operational amplifier OPC, a transistor TC6, and resistors RC3 and RC4. The voltage of the node NC6 becomes equivalent to the reference voltage VREF by virtual ground of the operational amplifier OPC, the fixed voltage VF (constant voltage) becomes a voltage represented by “VF=VREF×{(RC3+RC4)/RC4}.” Accordingly, the fixed voltage VF which does not depend on the power supply voltage can be output. Further, by a Power Supply Rejection Ratio (PSRR) of the operational amplifier OPC, it is possible to minimize fluctuation of the fixed voltage VF even when the power-supplied voltage fluctuates.

Therefore, according to the voltage generation circuit 90 having the configuration of FIG. 8, the fixed voltage VF whose fluctuation is minimized with respect to the fluctuation of the temperature or the fluctuation of a power supply is generated and can be supplied to the control unit 30. Further, by supplying the fixed voltage VF whose fluctuation is minimized as the applied voltages of the variable capacitance elements VA1 to VAn, it is possible to improve the frequency stability of the oscillating frequency.

### 4. Adjustment of Oscillating Frequency

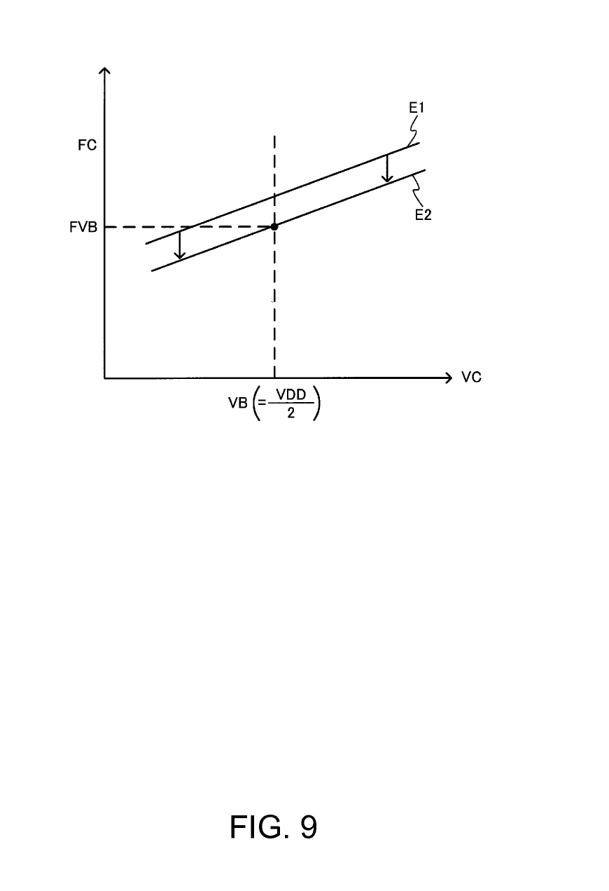

FIG. 9 is a view describing an example of a method of adjusting the oscillating frequency of the oscillator. For example, at the time of shipping products of oscillators, mechanical processing is added to the oscillation element 10 such as a crystal vibrator and the oscillating frequency of the oscillation element 10 itself is adjusted in a case where the oscillating frequency of the VCXO is adjusted.

In this case, the control voltage VC is set to the nominal frequency voltage VB corresponding to the above-described nominal frequency. The nominal frequency voltage VB is referred to as the center voltage and is set to “VB=VDD/2” which is the center voltage of the power supply voltage VDD. Further, required accuracy can be sufficiently obtained only with the mechanical processing of the oscillation element 10, but the variable capacitance circuits 62-1 and 62-2 of FIG. 4 are used for final minute adjustment of the oscillating frequency in a case where high accuracy is required. That is, the final adjustment is performed on the oscillating frequency by setting the capacitance values of the variable capacitance circuits 62-1 and 62-2 such that the oscillating frequency becomes the nominal frequency FVB in a case where the control voltage is “VC=VB=VDD/2” as illustrated in E1 and E2 of FIG. 9. That is, the final adjustment is performed on the oscillating frequency so as to be within the range of the nominal accuracy.

In this manner, adjustment of the oscillating frequency in the VCXO is realized. Further, in the present embodiment, as described above, both operations of the VCXO and the SPXO can be realized by setting the first and second operation modes. Accordingly, if the adjustment of the oscillating frequency can be completed as the SPXO by adjusting the oscillating frequency as the VCXO, the adjustment can be efficiently performed.

Accordingly, in the present embodiment, the voltage generation circuit 90 generates a voltage having a voltage value which is the same as that of the nominal frequency voltage VB as the fixed voltage VF in a case where the control voltage VC is set to the nominal frequency voltage VB at the time when the oscillating frequency is set to the nominal frequency FVB in the first operation mode. For example, in a case where the nominal frequency voltage is “VB=VDD/2” as illustrated in FIG. 9, the voltage generation circuit 90 generates a voltage of “VF=VB=VDD/2.” In the example of FIG. 8, such fixed voltage VF=VDD/2 can be generated by setting the resistance ratio of the resistors RC3 to RC4.

In this manner, after the oscillating frequency is adjusted in the first operation mode for the VCXO as illustrated in FIG. 9, the oscillating frequency of the SPXO can be set to the nominal frequency FVB by the voltage generation circuit 90 outputting the fixed voltage of “VF=VB=VDD/2” even in a case where the operation mode is switched to the second operation mode for the SPXO. Therefore, the adjustment of the oscillating frequency can be efficiently performed.

### 5. Electronic Apparatus and Moving Object

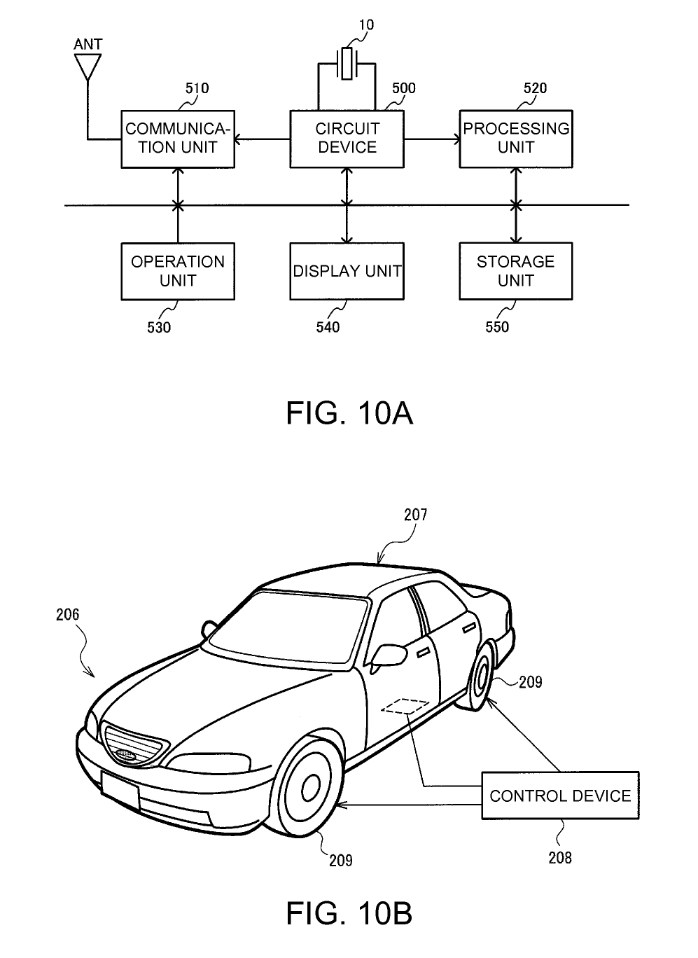

FIG. 10A illustrates a configuration example of an electronic apparatus including the circuit device of the present embodiment. The electronic apparatus includes a circuit device 500, an oscillation element 10, an antenna ATN, a communication unit 510, and a processing unit 520 of the present embodiment. Further, the electronic apparatus may further include an operation unit 530, a display unit 540, and a storage unit 550. As the electronic apparatus of FIG. 10A, for example, various equipment such as portable information terminals (a mobile phone and a smart phone), biometric equipment (a pulse monitor and a pedometer), and video equipment (a digital camera and a video camera) can be assumed.

The communication unit 510 (wireless circuit) performs a process of receiving data from the outside or a process of transmitting data to the outside through the antenna ANT. The processing unit 520 performs a process of controlling the electronic apparatus and a digital processing with respect to data which is transmitted or received through the communication unit 510.

An input operation of the operation unit 530 is performed by a user and the operation can be realized using an operation button or a touch panel display. The display unit 540 displays various pieces of information and can be realized by a liquid crystal or organic EL. The storage unit 550 stores data and can be realized by a semiconductor memory such as a RAM or a ROM or an HDD.

FIG. 10B illustrates an example of a moving object including the circuit device of the present embodiment. The circuit device of the present embodiment can be incorporated in, for example, various moving objects such as a vehicle, an airplane, a motorcycle, a bicycle, or a ship. The moving object is equipment or a device that includes a driving mechanism such as an engine or a motor, a steering mechanism such as a handle or a rudder, and various electronic apparatuses and moves the ground, the sky, or the sea. FIG. 10B schematically illustrates a vehicle 206 as a specific example of the moving object. The oscillator (not illustrated) including the circuit device and the oscillation element of the present embodiment is incorporated in the vehicle 206. A control device 208 is operated by a clock signal generated by the oscillator. The control device 208 controls the hardness of a suspension according to a posture of a vehicle body 207, and controls a brake of respective wheels 209.

In addition, the present embodiment has been described above, but it can be understood that various modifications are possible within the range without departing from new matters and effects of the invention by a person skilled in the art. Accordingly, such modifications are all assumed to be within the range of the invention. For example, when terms described with different terms having broad or similar meanings are used at least once in the specification or the figures, the terms can be replaced by different terms in any part of the specification or figures. Further, the configurations of the circuit device, the oscillator, the electronic apparatus, and the moving object are not limited to those described in the present embodiment and various modifications are possible.

The entire disclosure of Japanese Patent Application No. 2013-203865, filed Sep. 30, 2013 is expressly incorporated by reference herein.

What is claimed is:

1. A circuit device comprising:
an oscillation circuit that includes a variable capacitance circuit and performs an operation of oscillating an oscillation element; and
a control unit,
wherein the variable capacitance circuit includes first to n-th variable capacitance elements (where, n is an integer of 2 or more),
when an operation mode is a first operation mode, the control unit supplies first to n-th applied voltages in which at least one thereof is a variable voltage to the first to n-th variable capacitance elements, and
when the operation mode is a second operation mode, the control unit supplies the first to n-th applied voltages which are fixed voltages to the first to n-th variable capacitance elements.

2. The circuit device according to claim 1, further comprising an operation mode setting unit that sets the operation mode,
wherein the operation mode setting unit includes a storage unit that stores setting information of the operation mode, and
the control unit switches the first operation mode and the second operation mode based on the setting information.

3. The circuit device according to claim 1,
wherein the control unit switches the first operation mode and the second operation mode using a control signal to be input.

4. The circuit device according to claim 1,
wherein the control unit includes first to n-th switching units (where, n is an integer of 2 or more) to which the variable voltage and the fixed voltage are input, and which output a voltage selected from the variable voltage and the fixed voltage to the first to n-th variable capacitance elements as the first to n-th applied voltages,
when the operation mode is the first operation mode, at least one switching unit among the first to n-th switching units selects and outputs the variable voltage, and
when the operation mode is the second operation mode, the first to n-th switching units select and output the fixed voltage.

5. The circuit device according to claim 1, wherein the control unit sets frequency variable sensitivity of an oscillating frequency with respect to a control voltage which is the variable voltage by setting the number of times of supplying voltages which become variable voltages among the first to n-th applied voltages.

6. The circuit device according to claim 1, further comprising a voltage generation circuit that generates the fixed voltage based on a reference voltage.

7. The circuit device according to claim 6,
wherein the first operation mode is a mode in which the oscillating frequency is changed according to a change of the control voltage which is the variable voltage, and
when the control voltage is set as a nominal frequency voltage while the oscillating frequency is set as a nominal frequency in the first operation mode, the voltage generation circuit generates the nominal frequency voltage as the fixed voltage.

8. The circuit device according to claim 1, further comprising a control voltage input terminal to which the control voltage which is the variable voltage is input,
wherein the first operation mode is a mode in which the oscillating frequency is changed according to a change of the control voltage, and
the second operation mode is a mode in which the oscillating frequency is constant with respect to the change of the control voltage.

9. An oscillator comprising:
the circuit device according to claim 1, and
the oscillation element.

10. An electronic apparatus comprising the circuit device according to claim 1.

11. A moving object comprising the circuit device according to claim 1.
